(19) United States
(12) Patent Application Publication
(10) Pub. No.: US 2026/0082647 A1
(43) Pub. Date: Mar. 19, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yu-Chien CHIU, Hsinchu (TW); Chien-Hao HUANG, Hsinchu (TW); Ya-Yun CHENG, Hsinchu (TW); Wen-Ling LU, Hsinchu (TW); Chung-Wei WU, Hsinchu (TW); Zhiqiang WU, Hsinchu (TW)

(73) Assignee: Taiwan Semiconductor Manufacturing Company, Ltd., Hsinchu (TW)

(21) Appl. No.: 18/887,556

(22) Filed: Sep. 17, 2024

(51) Int. Cl. H01L 29/08; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121

(57) ABSTRACT

A semiconductor device includes a substrate, a transistor on the substrate and a transistor formed on the substrate. The transistor includes an active channel, a drain, a source, a second hydrogen absorption layer and a first hydrogen absorption layer. The active channel has a first end surface and a second end surface opposite to the first end surface. The drain is disposed adjacent to the first end surface of the active channel. The source is disposed adjacent to the second end surface of the active channel. The second hydrogen absorption layer separates the drain from the first end surface of the active channel. The first hydrogen absorption layer separates the source from the second end surface of the active channel.

### BACKGROUND

In metal formation process (for example, CVD), hydrogen doping may cause the doping of the active channel to continuously increase. Consequently, a high leakage and worse reliability due to hydrogen diffusion into the active channel, and a higher contact resistance between the active channel and the metal results in slower writing and reading speeds.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a semiconductor device according to an embodiment of the present disclosure;

FIG. 2 illustrates a schematic diagram of a semiconductor device according to another embodiment of the present disclosure;

FIG. 3 illustrates a schematic diagram of a semiconductor device according to another embodiment of the present disclosure;

FIG. 4 illustrates a flowchart of the manufacturing method of the semiconductor device according to an embodiment of the present disclosure;

FIGS. 5A to 5Q illustrate schematic diagrams of manufacturing processes of the semiconductor device in FIG. 1;

FIG. 6 illustrates schematic diagram of a manufacturing process of the semiconductor device in FIG. 2; and

FIGS. 7A to 7C illustrate schematic diagrams of manufacturing processes of the semiconductor device in FIG. 3.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

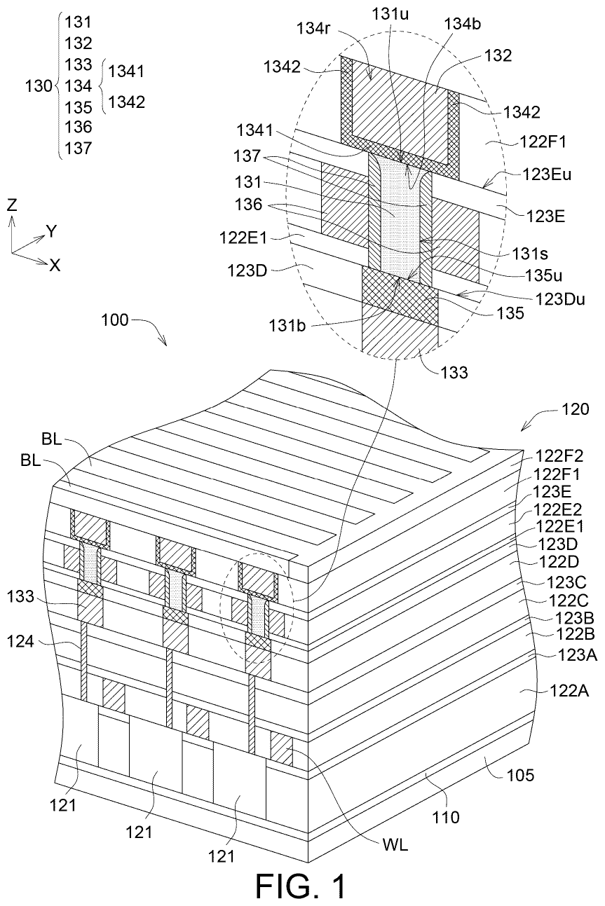

As illustrated in FIG. 1, FIG. 1 illustrates a schematic diagram of a semiconductor device 100 according to an embodiment of the present disclosure. The semiconductor device 100 includes a substrate 105, a FEOL (front-end-of-line) structure 110, a BEOL (back end of line) structure 120 and at least one transistor 130. The FEOL structure 110 is disposed between the substrate 105 and the BEOL structure 120. The FEOL structure 110 may include a plurality of transistors having Gate-all-around (GAA) structure, silicon nanosheet structure, Fin Field-Effect Transistor (FinFET) structure, etc.

As illustrated in FIG. 1, the BEOL structure 120 includes at least one memory component 121, a plurality of first insulation layers (for example, include 122A, 122B, 122C, 122D, 122E1, 122E2, 122F1 and 122F2), a plurality of second insulation layers (for example, include 123A, 123B, 123C, 123D, 123E) and at least one conductive via 124. The memory component 121 is, for example, DRAM (Dynamic Random Access Memory), MRAM (Magnetoresistive Random Access Memory), RRAM (Magnetoresistive Random Access Memory), PCRAM (phase-change memory), FTJ (Ferroelectric tunnel junction), capacitor, etc. One of the first insulation layer and the second insulation layer may separate two conductive layers (for example, the drain 132, the source 133, the second hydrogen absorption layer 134, the first hydrogen absorption layer 135 and the gate 136). One of the second insulation layers may be disposed between the adjacent two of the first insulation layers. For example, the second insulation layer 123A is disposed between the first insulation layer 122A and the first insulation layer 122B, and the first insulation layer 122B is disposed between the second insulation layer 123A and the second insulation layer 123B. In addition, the first insulation layers (for example, 122A, 122B, 122C, 122D, 122E1, 122E2, 122F1 and 122F2) may be formed of a material including, for example, oxide, and the second insulation layers (for example, include 123A, 123B, 123C, 123D, 123E) may be formed of a material including, for example, AlOx. The conductive via 124 is formed in at least one insulation layer and may electrically connect the source 133 and the memory component 121, for example, the first insulation layer 122B, the second insulation layer 123B, the first insulation layer 122C and the second insulation layer 123C. In addition, the first insulation layer and the second insulation layer may be formed of a material including, for example, oxide material.

As illustrated in FIG. 1, the transistor 130 is disposed on or in the BEOL structure 120. The transistor 130 includes an active channel 131, a drain (or second electrode) 132, a source (or first electrode) 133, a first hydrogen absorption layer (HAL) 135, a second hydrogen absorption layer 134, a gate 136 and a gate dielectric layer 137.

As illustrated in FIG. 1, the active channel 131, the drain 132, the source 133, the second hydrogen absorption layer 134, the first hydrogen absorption layer 135 are stacked in a vertical direction (for example, Z-axis). The active channel 131 is a vertical channel. The Z-axis is, for example, parallel to a thickness direction of the semiconductor device 100.

As illustrated in FIG. 1, the active channel 131 has a first end surface 131u and a second end surface 131b opposite to the first end surface 131u. The drain 132 is disposed adjacent to the first end surface 131u of the active channel 131. The source 133 is disposed adjacent to the second end surface 131b of the active channel 131. The second hydrogen absorption layer 134 may separate the drain 132 from the first end surface 131u of the active channel 131. The first hydrogen absorption layer 135 may separate the source 133 from the second end surface 131b of the active channel 131. The hydrogen absorption layer may absorb the hydrogen to prevent the hydrogen from entering active channel 131, and accordingly it may reduce the current leakage and increase the conductivity.

As shown in Table 1 below, in an embodiment, for the transistor 130 with the hydrogen absorption layer, the threshold voltage Vₜ may increase by about 0.25 voltage (V) compared with the threshold voltage V_{Ref} of the transistor without the hydrogen absorption layer, and the driving current I_{ON} may increase by about 2.1 times (2.1×) compared with the threshold voltage V_{Ref} of the transistor without the hydrogen absorption layer. The higher threshold voltage Vₜ may reduce the current leakage of the transistor 130, and the increased driving current I_{ON} may prove that the conductivity of the transistor 130 is increased. Furthermore, the hydrogen absorption with high doping may increase conductivity, and form an ohmic contact between the metal and the hydrogen absorption. As a result, it may increase the performance of the transistor, for example, writing and reading speeds of the transistor may be increased.

TABLE 1

| | transistor without | transistor 130 |
|---|---|---|
| | hydrogen absorption | with hydrogen |
| | layer | absorption layer |
| threshold voltage Vₜ | V_{Ref} | +0.25 V |
| driving current I_{ON} | 1× | 2.1× |

In the present embodiment, the drain 132 is disposed above the first end surface 131u, while the source 133 is disposed below the second end surface 131b. In another embodiment, the drain 132 and the source 133 may exchange in position, that is, the source 133 is disposed above the first end surface 131u, while the drain 132 is disposed below the second end surface 131b.

As illustrated in FIG. 1, the second hydrogen absorption layer 134 is disposed between the drain 132 and the first end surface 131u of the active channel 131 for separating the drain 132 from the active channel 131, and the first hydrogen absorption layer 135 is disposed between the source 133 and the second end surface 131b of the active channel 131 for separating the source 133 from the active channel 131.

As illustrated in FIG. 1, the second hydrogen absorption layer 134 has an absorption region 134r within which the drain 132 is disposed. Furthermore, the second hydrogen absorption layer 134 includes a bottom portion 1341 and a plurality of lateral portions 1342, wherein the lateral portions 1342 are connected with the bottom portion 1341. The bottom portion 1341 is disposed between the drain 132 from the active channel 131, and separates the drain 132 from the active channel 131. The bottom portion 1341 and the lateral portions 1342 form the absorption region 134r.

As illustrated in FIG. 1, the second hydrogen absorption layer 134 has a low surface 134b, and the low surface 134b of the second hydrogen absorption layer 134 overlaps the entirety of the first end surface 131u of the active channel 131 in Z-axis. In an embodiment, the low surface 134b has a width in X-axis greater than that of the first end surface 131u in X-axis.

In an embodiment, the first hydrogen absorption layer 135 is disposed within the insulation layer, for example, the second insulation layer 123D. The second insulation layer 123D has an upper surface 123Du, the first hydrogen absorption layer 135 has an upper surface 135u, and the upper surface 123Du of the second insulation layer 123D and the upper surface 135u of the first hydrogen absorption layer 13 are aligned (for example, flushed) with each other. The upper surface 135u of the first hydrogen absorption layer 135 is contact with the second end surface 131b. In addition, the upper surface 135u of the first hydrogen absorption layer 135 overlaps the entirety of the second end surface 131b of the active channel 131 in Z-axis. In an embodiment, the upper surface 135u has a width in X-axis greater than that of the second end surface 131b in X-axis.

As illustrated in FIG. 1, one (for example, the second insulation layers 123E) of the second insulation layers may separate the drain 132 (or the second hydrogen absorption layer 134) from the gate 136, and accordingly it may prevent the drain 132 from being electrically short-circuited to the gate 136. One (for example, the second insulation layer 123D) of the second insulation layers and one (the first insulation layers 122E1) of the first insulation layers may separate the source 133 (or the first hydrogen absorption layer 135) from the gate 136 and accordingly it may prevent the source 134 from being electrically short-circuited to the gate 136. The first end surface 131u is aligned (for example, flushed) with an upper surface 123Eu of the second insulation layer 123E.

As illustrated in FIG. 1, the gate 136 is disposed adjacent to at least one lateral surface 131s of the active channel 131. The gate dielectric layer 137 is disposed between the active channel 131 form the gate 136 for separating the active channel 131 form the gate 136.

In terms of materials, the active channel 131 is, for example, a N-type channel or a P-type channel. The N-type channel may be formed of a material including, for example, IGZO, ZnO, In2O3, SnO2, etc., and the P-type channel may be formed of a material including, for example, NiO, Cu2O, CuAlO2, CuGaO2, CuInO2, SrCu2O2, SnO, etc. The drain 132 and the source 133 may be formed of a material including, for example, TaN, TIN, W, Al, Poly, Ru, Co, Cu, ITO, etc. The hydrogen absorption layer (134 and/or 135) may be formed of a material including, for example, InO, TiO, ITO, CeO, ZnO, IGZO, etc. The gate 136 may be formed of a material including, for example, TaN, TIN, W, Al, poly silicon, etc. The gate dielectric layer 137 may be formed of a material with high dielectric constant (HK material) including, for example, HfO₂, SiO₂, Al2O₃, SiON, etc.

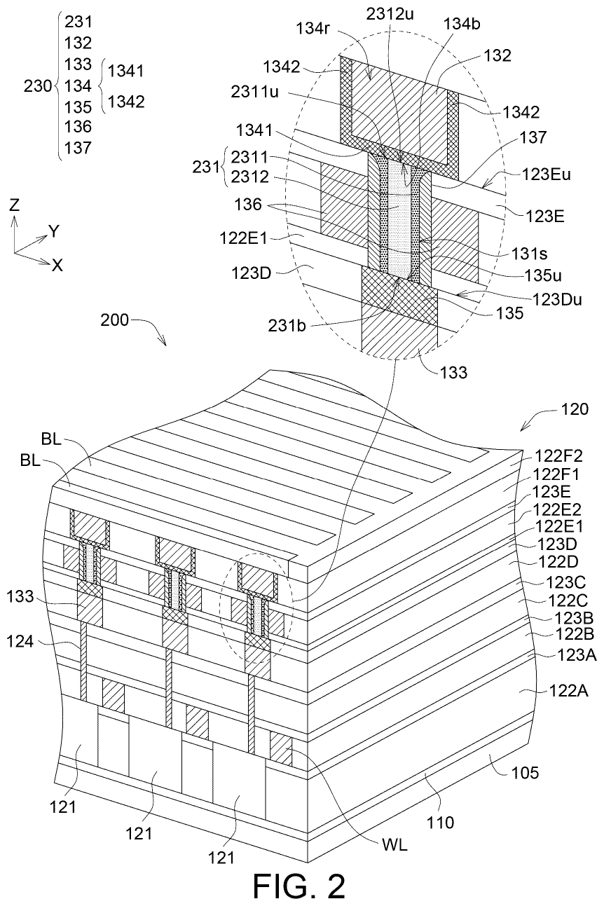

As illustrated in FIG. 2, FIG. 2 illustrates a schematic diagram of a semiconductor device 200 according to another embodiment of the present disclosure. The semiconductor device 200 includes the substrate 105, the FEOL structure 110, the BEOL structure 120 and at least one transistor 230. The FEOL structure 110 is disposed between the substrate 105 and the BEOL structure 120.

As illustrated in FIG. 2, the BEOL structure 120 includes at least one memory component 121, the plurality of first insulation layers (for example, include 122A, 122B, 122C, 122D, 122E1, 122E2, 122F1 and 122F2), the plurality of second insulation layers 123 (for example, include 123A, 123B, 123C, 123D, 123E) and at least one conductive via 124. The memory component 121 is, for example, DRAM, MRAM, RRAM, PCRAM, FTJ, capacitor, etc. One of the first insulation layer and the second insulation layer may separate two conductive layers (for example, the drain 132, the source 133, the second hydrogen absorption layer 134, the first hydrogen absorption layer 135 and the gate 136). One of the second insulation layers may be disposed between the adjacent two of the first insulation layers. For example, the second insulation layer 123A is disposed between the first insulation layer 122A and the first insulation layer 122B, and the first insulation layer 122B is disposed between the second insulation layer 123A and the second insulation layer 123B. In addition, the first insulation layers (for example, 122A, 122B, 122C, 122D, 122E1, 122E2, 122F1 and 122F2) may be formed of a material including, for example, oxide, and the second insulation layers (for example, include 123A, 123B, 123C, 123D, 123E) may be formed of a material including, for example, AlOx. The conductive via 124 may electrically connect the source 133 and the memory component 121 through at least one insulation layer, for example, the second insulation layer 123A, the first insulation layer 122B, the second insulation layer 123B, the first insulation layer 122C and the second insulation layer 123C.

As illustrated in FIG. 2, the transistor 230 is disposed on or in the BEOL structure 120. The transistor 230 includes the active channel 231, the drain 132, the source 133, the second hydrogen absorption layer 134, the first hydrogen absorption layer 135, the gate 136 and the gate dielectric layer 137.

As illustrated in FIG. 2, the transistor 230 includes the features the same as or similar to that of the transistor 130, and at least one difference is that the active channel 231 and the active channel 131 are different in structure. The active channel 231 is a multi-layered channel for improving performance and enhance reliability. Furthermore, the active channel 231 includes a first sub-channel 2311 and a second sub-channel 2312, wherein the first sub-channel 2311 is, for example, a high doping channel, and the second sub-channel 2312 is, for example, a low doping channel. The first sub-channel 2311 is formed over a sidewall of the gate dielectric layer 137. The second sub-channel 2312 is formed over a sidewall of the first sub-channel 2311, and the first sub-channel 2311 may surround the second sub-channel 2312.

As illustrated in FIG. 2, the active channel 231 has a first end surface (for example, 2311u and 2312u) and a second end surface 231b opposite to the first end surface. Furthermore, the first sub-channel 2311 has a first sub-end surface 2311u, and the second sub-channel 2312 has a second sub-end surface 2312u, wherein the first sub-end surface 2311u and the second sub-end surface 2312u are opposite to the second end surface 231b. The first sub-end surface 2311u and the second sub-end surface 2312u are aligned (for example, flushed) with each other. The drain 132 is disposed adjacent to the first sub-end surface 2311u and the second sub-end surface 2312u of the active channel 231. The source 133 is disposed adjacent to the second end surface 231b of the active channel 231. The second hydrogen absorption layer 134 is disposed between the drain 132 and the first sub-end surface 2311u and the second sub-end surface 2312u of the active channel 231. The first hydrogen absorption layer 135 is disposed between the source 133 and the second end surface 231b of the active channel 231. The hydrogen absorption layer may absorb the hydrogen to prevent the hydrogen from entering active channel 131, and accordingly it may accordingly it may reduce the current leakage and increase the conductivity.

As illustrated in FIG. 2, the second hydrogen absorption layer 134 is disposed between the drain 132 and the sub-end surfaces (the first sub-end surface 2311u and the second sub-end surface 2312u) of the active channel 231 for separating the drain 132 from the active channel 231, and the first hydrogen absorption layer 135 is disposed between the source 133 and the second end surface 231b of the active channel 231 for separating the source 133 from the active channel 231.

As illustrated in FIG. 2, the second hydrogen absorption layer 134 has an absorption region 134r within which the drain 132 is disposed. Furthermore, the second hydrogen absorption layer 134 includes the bottom portion 1341 and a plurality of lateral portions 1342, wherein the lateral portions 1342 are connected with the bottom portion 1341. The bottom portion 1341 and the lateral portions 1342 form the absorption region 134r. The bottom portion 1341 separates the drain 132 from the active channel 231.

In an embodiment, the first hydrogen absorption layer 135 is disposed within the insulation layer, for example, the second insulation layer 123D. The second insulation layer 123D has the upper surface 123Du, the first hydrogen absorption layer 135 has an upper surface 135u, and the upper surface 123Du of the second insulation layer 123D and the upper surface 135u of the first hydrogen absorption layer 13 are aligned (for example, flushed) with each other. The upper surface 135u of the first hydrogen absorption layer 135 is contact with the second end surface 231b.

As illustrated in FIG. 2, the second insulation layer 123E may separate the drain 132 from the gate 136, and accordingly it may prevent the drain 132 from being electrically short-circuited to the gate 136. The second insulation layer 123D and the first insulation layers 122E1 may separate the source 133 from the gate 136 and accordingly it may prevent the source 134 from being electrically short-circuited to the gate 136. The first sub-end surface 2311u and the second sub-end surface 2312u of the active channel 231 are aligned (for example, flushed) with an upper surface 123Eu of the second insulation layer 123E.

As illustrated in FIG. 2, the gate 136 is disposed adjacent to at least one lateral surface 231s of the active channel 231. The gate dielectric layer 137 is disposed between the active channel 231 form the gate 136 for separating the active channel 231 form the gate 136.

In terms of materials, the first sub-channel 2311 and the second sub-channel 2312 of active channel 231 is, for example, a N-type channel or a P-type channel. The N-type channel may be formed of a material including, for example, IGZO, ZnO, In₂O₃, SnO₂, etc., and the P-type channel may be formed of a material including, for example, NiO, Cu₂O, CuAlO₂, CuGaO₂, CuInO₂, SrCu₂O₂, SnO, etc.

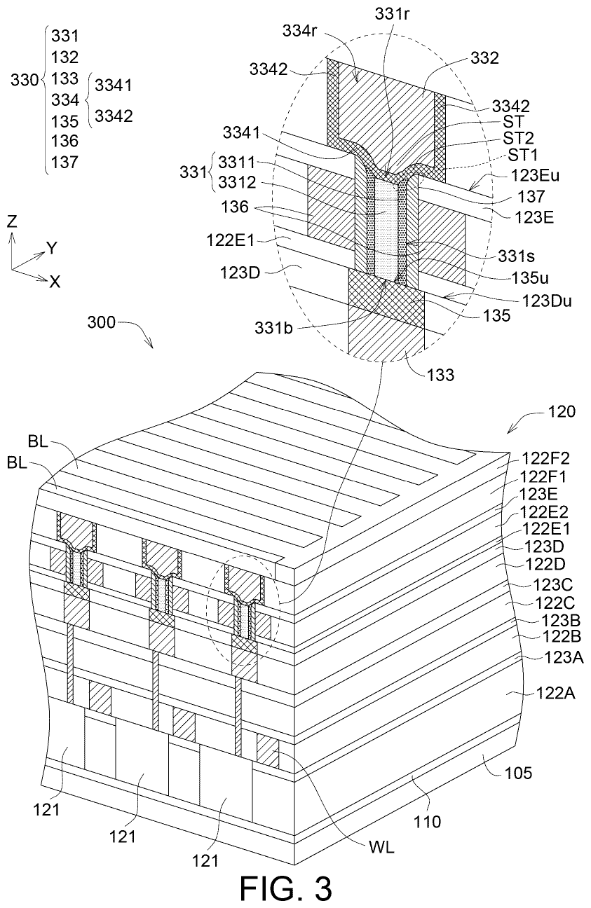

As illustrated in FIG. 3, FIG. 3 illustrates a schematic diagram of a semiconductor device 300 according to another embodiment of the present disclosure. The semiconductor device 300 includes the substrate 105, the FEOL structure 110, the BEOL structure 120 and at least one transistor 330. The FEOL structure 110 is disposed between the substrate 105 and the BEOL structure 120.

As illustrated in FIG. 3, the BEOL structure 120 includes at least one memory component 121, the plurality of first insulation layers (for example, include 122A, 122B, 122C, 122D, 122E1, 122E2, 122F1 and 122F2), the plurality of second insulation layers (for example, include 123A, 123B, 123C, 123D, 123E) and at least one conductive via 124. The memory component 121 is, for example, DRAM, MRAM, RRAM, PCRAM, FTJ, capacitor, etc. One of the first insulation layer and the second insulation layer may separate two conductive layers (for example, the drain 332, the source 133, the second hydrogen absorption layer 134, the first hydrogen absorption layer 135 and the gate 136). One of the second insulation layers may be disposed between the adjacent two of the first insulation layers. For example, the second insulation layer 123A is disposed between the first insulation layer 122A and the first insulation layer 122B, and the first insulation layer 122B is disposed between the second insulation layer 123A and the second insulation layer 123B. In addition, the first insulation layers (for example, 122A, 122B, 122C, 122D, 122E1, 122E2, 122F1 and 122F2) may be formed of a material including, for example, oxide, and the second insulation layers (for example, include 123A, 123B, 123C, 123D, 123E) may be formed of a material including, for example, AlOx. The conductive via 124 may electrically connect the source 133 and the memory component 121 through at least one insulation layer, for example, the second insulation layer 123A, the first insulation layer 122B, the second insulation layer 123B, the first insulation layer 122C and the second insulation layer 123C.

As illustrated in FIG. 3, the transistor 330 is disposed on or in the BEOL structure 120. The transistor 330 includes the active channel 331, the drain 332, the source 133, a second hydrogen absorption layer 334, the first hydrogen absorption layer 135, the gate 136 and the gate dielectric layer 137.

As illustrated in FIG. 3, the transistor 330 includes the features the same as or similar to that of the transistor 130, and at least one difference is that the active channel 331 and the active channel 131 are different in structure. The active channel 331 is a multi-layered channel for improving performance and enhance reliability. Furthermore, the active channel 331 includes a first sub-channel 3311 and a second sub-channel 3312, wherein the first sub-channel 3311 is, for example, a high doping channel, and the second sub-channel 3312 is, for example, a low doping channel. The first sub-channel 3311 is formed over a sidewall of the gate dielectric layer 137. The second sub-channel 3312 is formed over a sidewall of the first sub-channel 3311, and the first sub-channel 3311 may surround the second sub-channel 3312.

As illustrated in FIG. 3, in the present embodiment, the active channel 331 has a first stepped structure ST1. Furthermore, the active channel 331 has a channel region 331r extending to the second sub-channel 3312 from the first sub-channel 3311 to form the first stepped structure S1. The channel region 331r is formed in an etching process for the active channel 331. In addition, the first sub-channel 3311 and the second sub-channel 3312 are lower than an upper surface of the gate dielectric layer 137 or the upper surface 123Eu of the second insulation layer 123E in Z-axis after the etching process for the active channel 331. In the etching process, the etching rate for the second sub-channel 3312 is faster than the etching rate for the first sub-channel 3311, and thus the second sub-channel 3312 may form a terminal surface lower than the terminal surface of the first sub-channel 3311 in Z-axis.

As illustrated in FIG. 3, the drain 332 is formed over the active channel 331 and has a stepped structure ST corresponding to or matching the shape of the first stepped structure ST1 of the active channel 331. The second hydrogen absorption layer 334 is disposed between the drain 332 and the active channel 331. The source 133 is disposed adjacent to a second end surface 331b of the active channel 331. The first hydrogen absorption layer 135 is disposed between the source 133 and a second end surface 331b of the active channel 331. The hydrogen absorption layer may absorb the hydrogen to prevent the hydrogen from entering active channel 131, and accordingly it may reduce the current leakage and increase the conductivity.

As illustrated in FIG. 3, the second hydrogen absorption layer 334 is disposed between the drain 332 and the active channel 331 for separating the drain 332 from the active channel 331, and the first hydrogen absorption layer 135 is disposed between the source 133 and the second end surface 331b of the active channel 331 for separating the source 133 from the active channel 331.

As illustrated in FIG. 3, the second hydrogen absorption layer 334 has the absorption region 334r within which the drain 332 is disposed. Furthermore, the second hydrogen absorption layer 334 includes a bottom portion 3341 and a plurality of lateral portions 3342, wherein the lateral portions 3342 are connected with the bottom portion 3341. The bottom portion 3341 and the lateral portions 3342 form or surround the absorption region 334r. The bottom portion 3341 separates the drain 332 from the active channel 331. The bottom portion 3341 has a second stepped structure ST2 corresponding to or matching the shape of the first stepped structure ST1 of the active channel 331.

In an embodiment, the first hydrogen absorption layer 135 is disposed within the insulation layer, for example, the second insulation layer 123D. The second insulation layer 123D has the upper surface 123Du, the first hydrogen absorption layer 135 has an upper surface 135u, and the upper surface 123Du of the second insulation layer 123D and the upper surface 135u of the first hydrogen absorption layer 135 are aligned (for example, flushed) with each other. The upper surface 135u of the first hydrogen absorption layer 135 is contact with the second end surface 331b.

As illustrated in FIG. 3, the second insulation layer 123E may separate the drain 332 from the gate 136, and accordingly it may prevent the drain 332 from being electrically short-circuited to the gate 136. The second insulation layer 123D and the first insulation layers 122E1 may separate the source 133 from the gate 136 and accordingly it may prevent the source 334 from being electrically short-circuited to the gate 136.

As illustrated in FIG. 3, the gate 136 is disposed adjacent to at least one lateral surface 331s of the active channel 331. The gate dielectric layer 137 is disposed between the active channel 331 and the gate 136 for separating the active channel 331 form the gate 136.

In terms of materials, the active channel 331 is, for example, a N-type channel or a P-type channel. The N-type channel may be formed of a material including, for example, IGZO, ZnO, In₂O₃, SnO₂, etc., and the P-type channel may be formed of a material including, for example, NiO, Cu₂O, CuAlO₂, CuGaO₂, CuInO₂, SrCu₂O₂, SnO, etc.

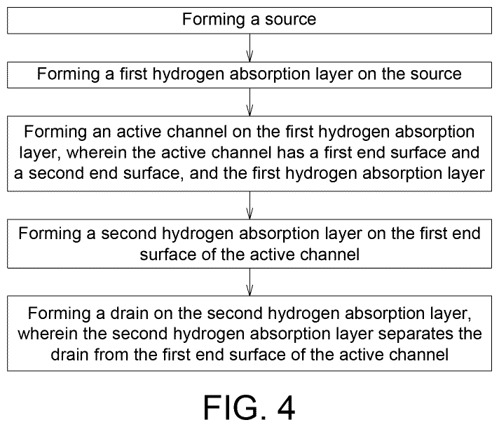

Referring to FIG. 4, FIG. 4 illustrates a flowchart of the manufacturing method of the semiconductor device according to an embodiment of the present disclosure. Firstly, a substrate (for example, silicon wafer) is provided. Then, the FEOL structure is formed on the substrate. Then, the BEOL structure is formed on the FEOL structure, and a transistor is formed in the BEOL structure. The transistor may be formed by at least steps S110 to S150 as illustrated in FIG. 4.

In step S110, the source is formed.

In step S120, the first hydrogen absorption layer is formed on the source.

In step S130, the active channel is formed on the first hydrogen absorption layer, wherein the active channel has the first end surface and a second end surface, and the first hydrogen absorption layer separates the source from the second end surface.

In step S140, the second hydrogen absorption layer is formed on the first end surface of the active channel.

In step S150, the drain is formed on the second hydrogen absorption layer, wherein the second hydrogen absorption layer separates the drain from the first end surface of the active channel.

The following further illustrates the manufacturing process of the semiconductor device in the present disclosure e with figures.

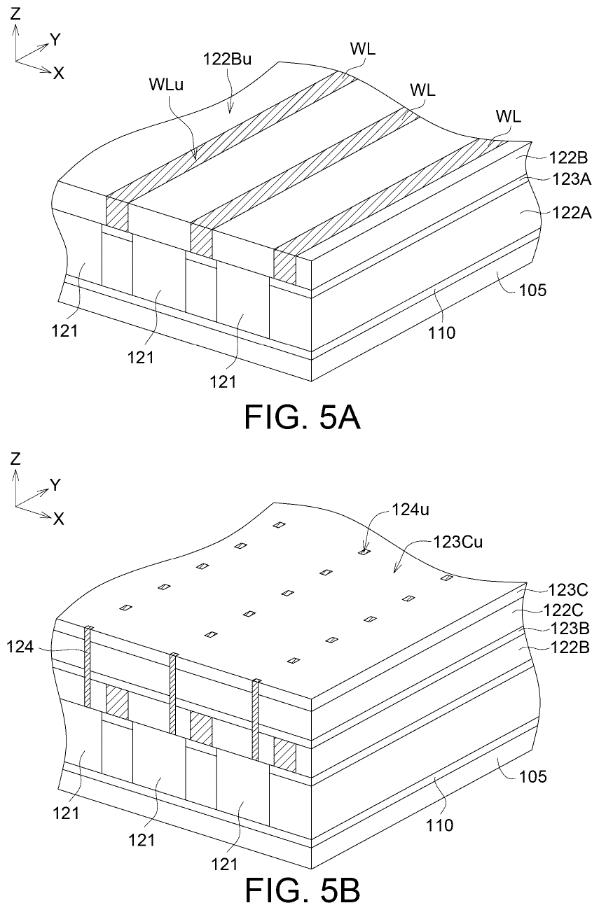

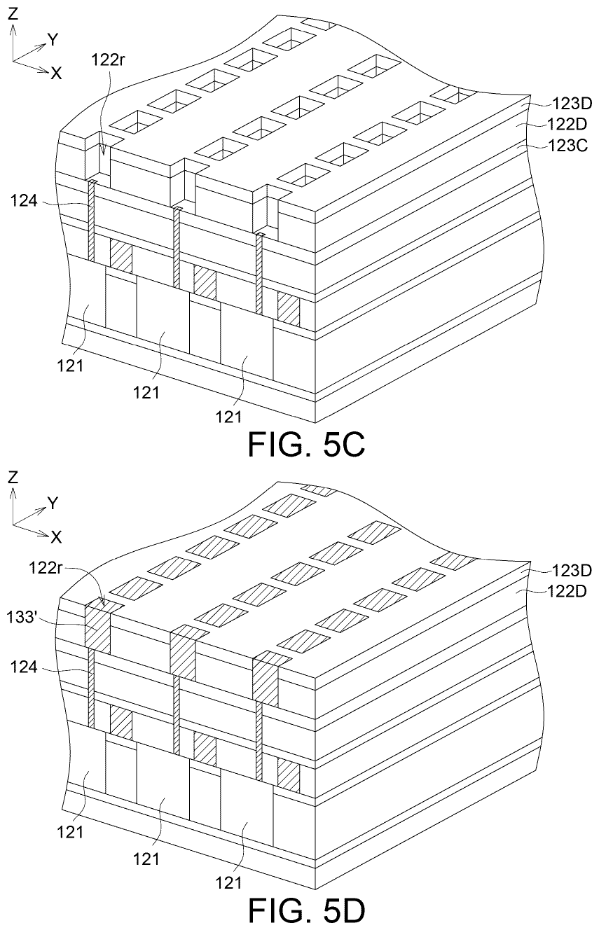

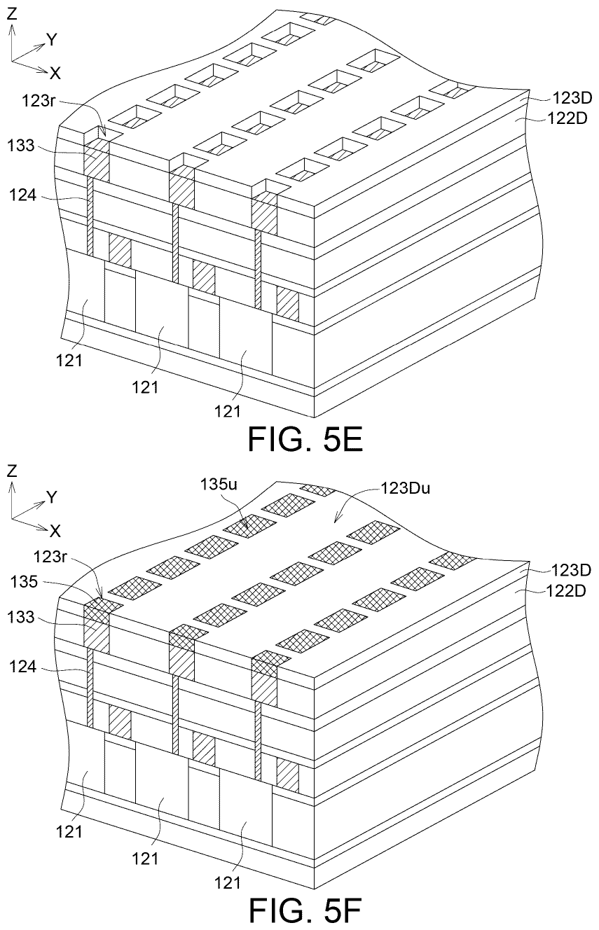

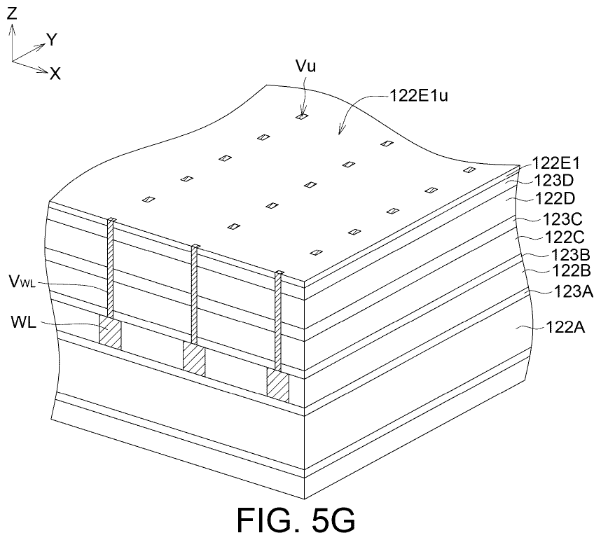

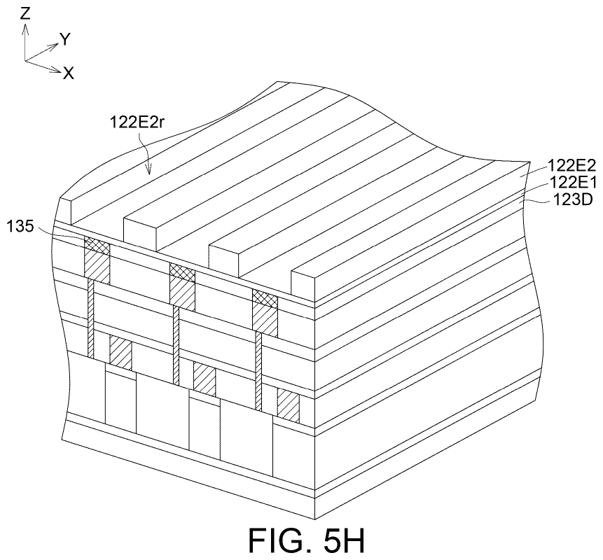

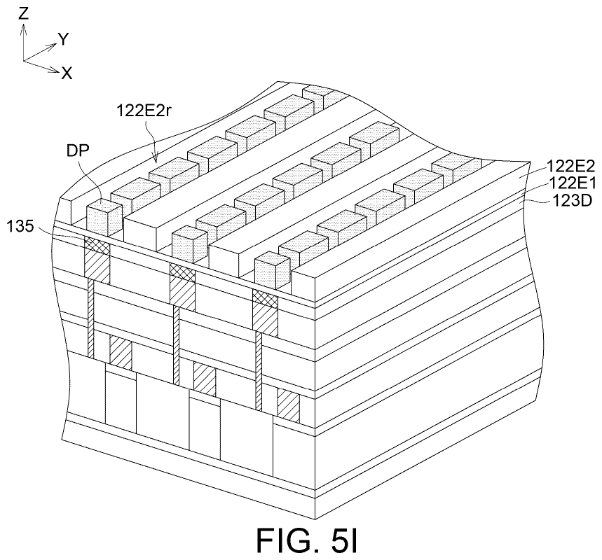

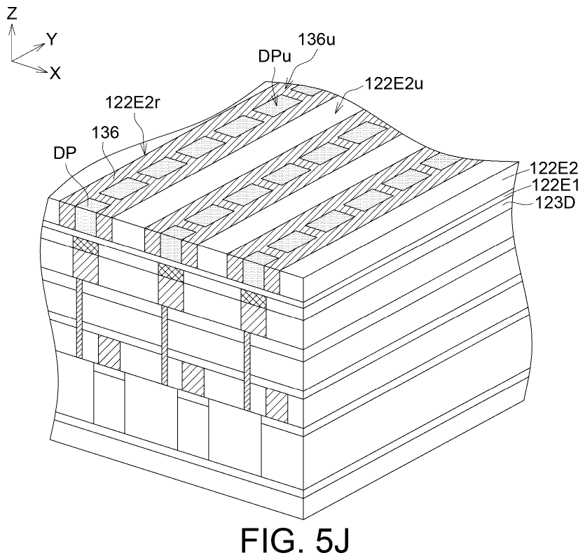

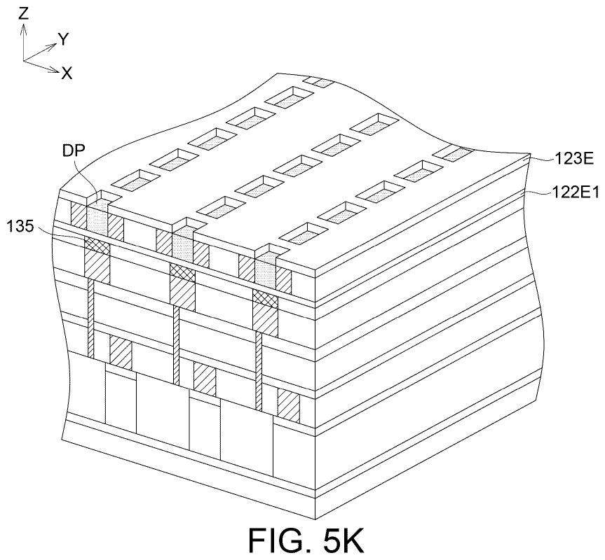

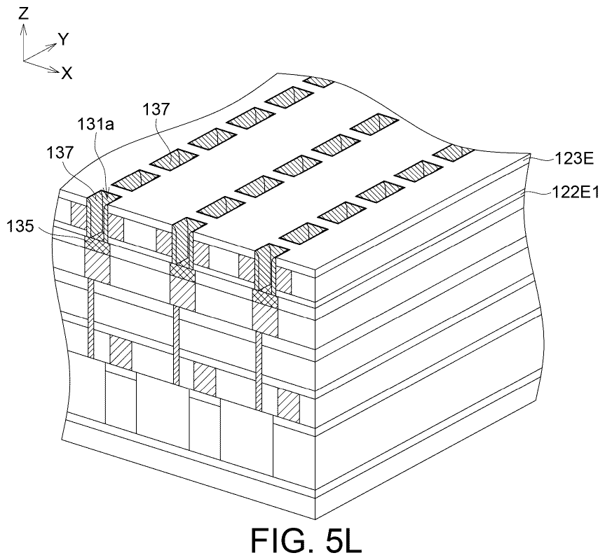

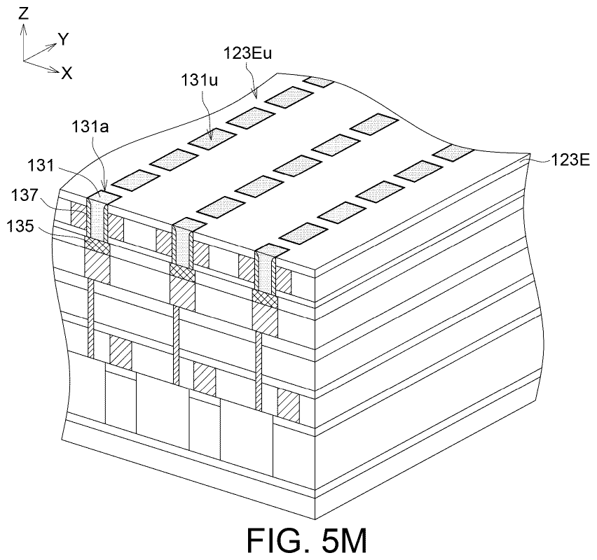

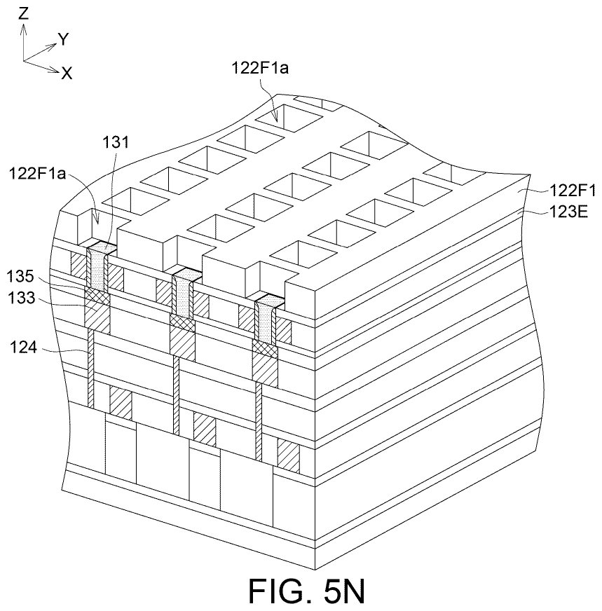

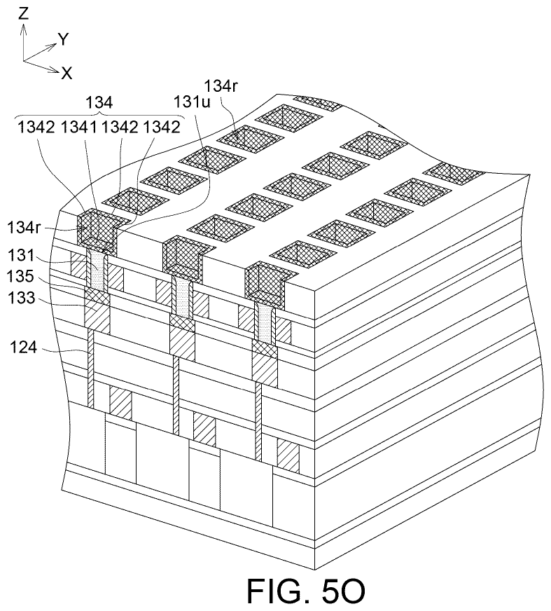

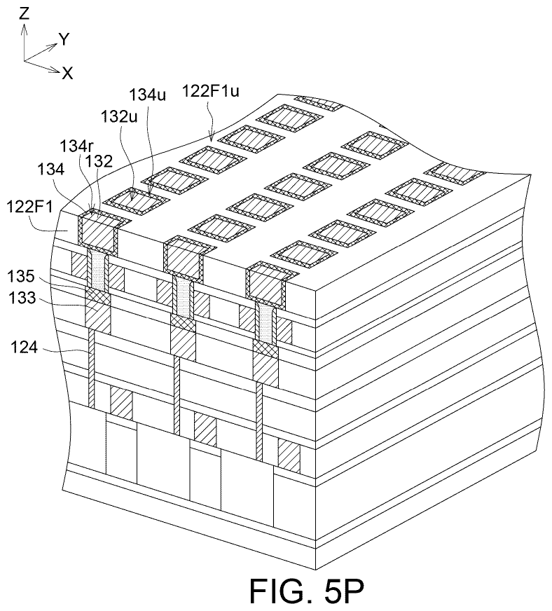

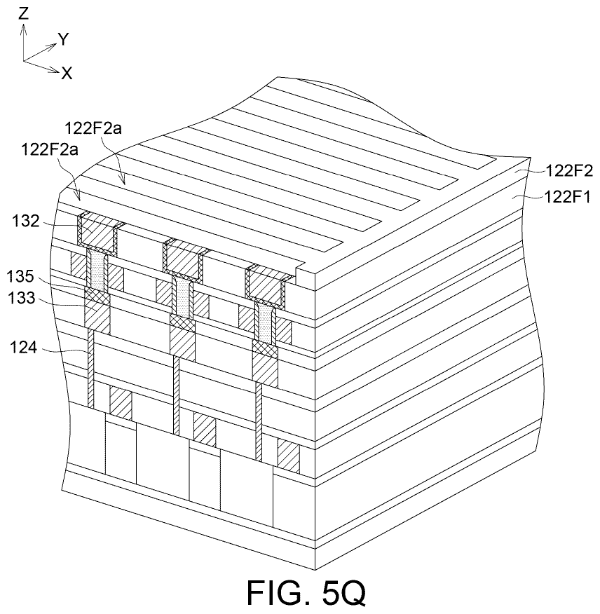

FIGS. 5A to 5Q illustrate schematic diagrams of manufacturing processes of the semiconductor device 100 in FIG. 1.

As illustrated in FIG. 5A, the first insulation layer 122A and a plurality of the memory components 121 are formed on the FEOL structure 110, wherein the first insulation layer 122A surround the memory components 121 for separating the memory components 121. The second insulation layer 123A is formed over the first insulation layer 122A by, for example, deposition. The first insulation layer 122B is formed over the second insulation layer 123A by, for example, deposition. A plurality of word lines WL, extending in Y-axis, is formed on the second insulation layer 123A through the first insulation layer 122B. The first insulation layer 122B may be patterned to form a plurality of openings by using any suitable process, such as by utilizing a patterned photoresist and an etching process, such as a wet or dry etching process. The word lines WL are formed within the openings of the first insulation layer 122B by, for example, deposition, etc. In addition, the first insulation layer 122B and the word lines WL may be planarized by, for example, a CMP (Chemical-Mechanical Planarization), etc. After planarized, the first insulation layer 122B and the word lines WL form a CMP surface. Furthermore, the word line WL forms an upper surface WLu, and the first insulation layer 122B forms an upper surface 122Bu, wherein the upper surface WLu and the upper surface 122Bu are aligned (for example, flushed) with each other.

Herein, “deposition processes” may include a chemical vapor deposition (CVD) process, a physical vapor deposition (PVD) process, an atomic layer deposition (ALD) process, a high density plasma CVD (HDPCVD) process, a metal organic CVD (MOCVD) process, a plasma enhanced CVD (PECVD) process, a sputtering process, or the like.

As illustrated in FIG. 5B, the second insulation layer 123B is formed over the first insulation layer 122B by, for example, deposition, the first insulation layer 122C is formed over the second insulation layer 123B by, for example, deposition, the second insulation layer 123C is formed over the first insulation layer 122C by, for example, deposition. A plurality of the conductive via 124 connected with the memory component 121 is formed through the first insulation layer 122B, the second insulation layer 123B, the first insulation layer 122C and the second insulation layer 123C. In addition, the second insulation layers 123C and the conductive vias 124 may be planarized by, for example, CMP, etc. After planarized, the second insulation layers 123C and the conductive vias 124 form a CMP surface. Furthermore, the second insulation layer 123C forms an upper surface 123Cu, and the conductive vias 124 forms an upper surface 124u, wherein the upper surface 123Cu and the upper surface 124u are aligned (for example, flushed) with each other.

As illustrated in FIG. 5C, the first insulation layer 122D is formed over the second insulation layer 123C by, for example, deposition, and the second insulation layer 123D is formed over the first insulation layer 122D by, for example, deposition. A plurality of holes 122r exposing the conductive via 124 is formed through the first insulation layer 122D and the second insulation layer 123D by, for example, patterned process, etc. The first insulation layer 122D and the second insulation layer 123D may be patterned by using any suitable process, such as by utilizing a patterned photoresist and an etching process, such as a wet or dry etching process.

As illustrated in FIG. 5D, a plurality of the source material 133′ is formed within (or fills) the holes 122r.

As illustrated in FIG. 5E, a portion of the source material 133′ is removed to form a plurality of holes 123r by, for example, pull back, such as ALE (atomic layer etching). After removed, a retained portion of the source material 133′ forms a plurality of the sources 133.

As illustrated in FIG. 5F, a plurality of the first hydrogen absorption layers 135 is formed within (or fills) the holes 123r. The first hydrogen absorption layers 135 may be formed of including a material, for example, InO, TiO, ITO, CeO, ZnO, IGZO and so on. In some embodiment, the first hydrogen absorption layers 135 may formed by, deposition. In addition, the second insulation layer 123D and the first hydrogen absorption layers 135 may be planarized by, for example, CMP, etc. After planarized, the second insulation layer 123D and the first hydrogen absorption layers 135 form a CMP surface. Furthermore, after planarized, the first hydrogen absorption layer 135 forms the upper surface 135u, and the second insulation layer 123D forms the upper surface 123Du, wherein the upper surface 135u and the upper surface 123Du are aligned (for example, flushed) with each other.

As illustrated in FIG. 5G, in another cross-sectional view, the first insulation layer 122E1 is formed over the second insulation layer 123D by, for example, deposition. A plurality of the conductive vias VWL connected with the word lines WL is formed through the first insulation layer 122E1, the second insulation layer 123D, the first insulation layer 122D, the second insulation layer 123C, the first insulation layer 122C, the second insulation layer 123B, the first insulation layer 122B, the second insulation layer 123A and the first insulation layer 122A. In some embodiment, the conductive via VwL is formed by, for example, patterned process, deposition, etc. In addition, the first insulation layer 122E1 and the conductive vias VWL may be planarized by, for example, CMP, etc. After planarized, the first insulation layer 122E1 and the conductive vias VWL form a CMP surface. Furthermore, the first insulation layer 122E1 forms the upper surface 122E1u, and the conductive via VwL forms the upper surface Vu, wherein the upper surface 122E1u and the upper surface Vu are aligned (for example, flushed) with each other.

As illustrated in FIG. 5H, the first insulation layer 122E2 is formed over the first insulation layer 122E1 by, for example, deposition. The first insulation layer 122E2 may be patterned to form a plurality of holes 122E2r. The first insulation layer 122E2 may be patterned by using any suitable process, such as by utilizing a patterned photoresist and an etching process, such as a wet or dry etching process. The holes 122E2r are corresponding to the first hydrogen absorption layer 135 in Z-axis, and the hole 122E2r extends in Y-axis. The holes 122E2r stop at the first insulation layer 122E1 in an etching process.

As illustrated in FIG. 5I, a plurality of dummy portions DP in the holes 122E2r is formed by, for example, deposition. The dummy portions DP may be formed of a material including, for example, silicon nitride (SiNx), etc. The dummy portion DP defines the region of the active channels. The hole 122E2r includes a first space which is occupied by the dummy portion DP and a second space which is not occupied by the dummy portion DP, and the second space defines the region of the gates 136. In an embodiment, the dummy portion DP is an island-like structure inside the hole 122E2r. The dummy portion DP may be shaped as polyhedron, such as cube, cuboid, etc.

As illustrated in FIG. 5J, a plurality of the gates 136 in the second space of the holes 122E2r which is not occupied by the dummy portion DP is formed by, for example, deposition. The gates 136 and the dummy portions DP fill the entirety of the holes 122E2r. In addition, the first insulation layer 122E2, the dummy portions DP and the gates 136 may be planarized by, for example, CMP, etc. After planarized, the first insulation layer 122E2, the dummy portions DP and the gates 136 may form a CMP surface. Furthermore, the first insulation layer 122E forms an upper surface 122E2u, the dummy portion DP forms an upper surface DPu and the gate 136 forms an upper surface 136u, wherein the upper surface 122E2u, the upper surface DPu and the upper surface 136u are aligned (for example, flushed) with each other.

As illustrated in FIG. 5K, the second insulation layer 123E is formed over the first insulation layer 122E1 by, for example, deposition. The second insulation layer 123E may be patterned to expose the dummy portions DP by using any suitable process, such as by utilizing a patterned photoresist and an etching process, such as a wet or dry etching process.

As illustrated in FIG. 5L, the dummy portions DP in FIG. 5K are removed to form a plurality of holes 131a by, for example, etching, etc. The hole 131a extends to the first hydrogen absorption layer 135 (to expose the first hydrogen absorption layer 135) through the first insulation layer 122E1 and the second insulation layer 123E. Then, a plurality of the gate dielectric layers 137 is formed on sidewalls of the holes 131a.

As illustrated in FIG. 5M, a plurality of the active channels 131 is formed within (or fill) the holes 131a and cover sidewalls of the gate dielectric layers 137. The active channel 131 is contact with the first hydrogen absorption layer 135. In addition, the second insulation layer 123E and the active channel 131 may be planarized by, for example, CMP, etc. After planarized, the second insulation layer 123E and the active channel 131 form a CMP surface. Furthermore, the second insulation layer 123E forms the upper surface 123Eu, and the active channel 131 forms the upper surface 131u, wherein the upper surface 123Eu and the upper surface 131u are aligned (for example, flushed) with each other.

As illustrated in FIG. 5N, the first insulation layer 122F1 is formed over the second insulation layer 123E by, for example, deposition. The first insulation layer 122F1 is patterned to form a plurality of holes 122F1a to expose the active channels 131. The first insulation layer 122F1 may be patterned by using any suitable process, such as by utilizing a patterned photoresist and an etching process, such as a wet or dry etching process.

As illustrated in FIG. 5O, the second hydrogen absorption layer 134 over sidewalls of the hole 122F1a in FIG. 5N and the upper surface 131u of the active channel 131 is formed by, for example, deposition. The second hydrogen absorption layer 134 includes the bottom portion 1341 and a plurality of the lateral portions 1342, wherein the lateral portions 1342 are connected with the bottom portion 1341. The bottom portion 1341 covers the upper surface of the active channels 131, and the lateral portions 1342 cover sidewalls of the hole 122F1a. The bottom portion 1341 and the lateral portions 1342 form or surround the absorption region (or recess) 134r.

As illustrated in FIG. 5P, a plurality of the drains 132 within the absorption regions 134r and over the second hydrogen absorption layer 134 is formed by, for example, deposition. In addition, the first insulation layer 122F1, the second hydrogen absorption layer 134 and the drain 132 may be planarized by, for example, CMP, etc. After planarized, the first insulation layer 122F1, the second hydrogen absorption layer 134 and the drain 132 form a CMP surface. Furthermore, the first insulation layer 122F1 forms the upper surface 122F1u, the second hydrogen absorption layer 134 forms an upper surface 134u and the drain 132 forms the upper surface 132u, wherein the upper surface 122F1u, the upper surface 134u and the upper surface 132u are aligned (for example, flushed) with each other.

As illustrated in FIG. 5Q, the first insulation layer 122F2 is formed over the first insulation layer 122F1 by, for example, deposition. The first insulation layer 122F2 is patterned to form a plurality of holes 122F2a. The holes 122F2a are corresponding to at least one drain 132 in Z-axis, expose the at least one drain 132, and the hole 122F2a extends in X-axis. The first insulation layer 122F2 may be patterned by using any suitable process, such as by utilizing a patterned photoresist and an etching process, such as a wet or dry etching process.

Then, a plurality of bit lines BL in FIG. 1 is formed within the holes 122F2a, wherein the bit lines BL are connected with the at least one drain 132.

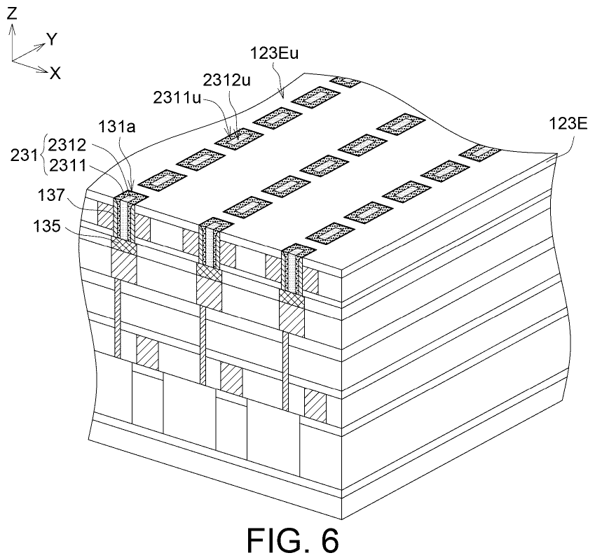

FIG. 6 illustrates schematic diagram of a manufacturing process of the semiconductor device 200 in FIG. 2.

The manufacturing method of the semiconductor device 200 includes the steps the same as or similar to that (FIGS. 5A to 5L and 5N to 5Q) of the semiconductor device 100, and the difference is that the forming step of the active channel 231. The difference is described below with FIG. 6, and other similar or the same steps will not be repeated here.

As illustrated in FIG. 6, a plurality of the active channels 231 is formed within (or fill) the holes 131a and cover sidewalls of the gate dielectric layers 137. The active channel 231 is contact with the first hydrogen absorption layer 135. The active channel 231 includes the first sub-channel 2311 and the second sub-channel 2312, wherein the first sub-channel 2311 is, for example, the high doping channel, and the second sub-channel 2312 is, for example, the low doping channel. The first sub-channel 2311 is formed over a sidewall of the gate dielectric layer 137. The second sub-channel 2312 is formed over a sidewall of the first sub-channel 2311, and the first sub-channel 2311 may surround the second sub-channel 2312. In addition, the second insulation layer 123E and the active channel 231 may be planarized by, for example, CMP, etc. After planarized, the second insulation layer 123E and the active channel 231 form a CMP surface. Furthermore, the second insulation layer 123E forms the upper surface 123Eu, the first sub-channel 2311 forms the first sub-end surface 2311u, and the second sub-channel 2312 forms the second sub-end surface 2312u, wherein the upper surface 123Eu, the first sub-end surface 2311u and the second sub-end surface 2312u are aligned (for example, flushed) with each other.

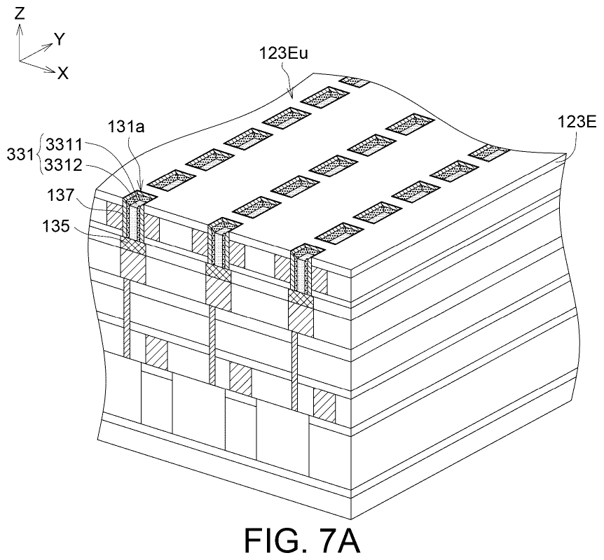

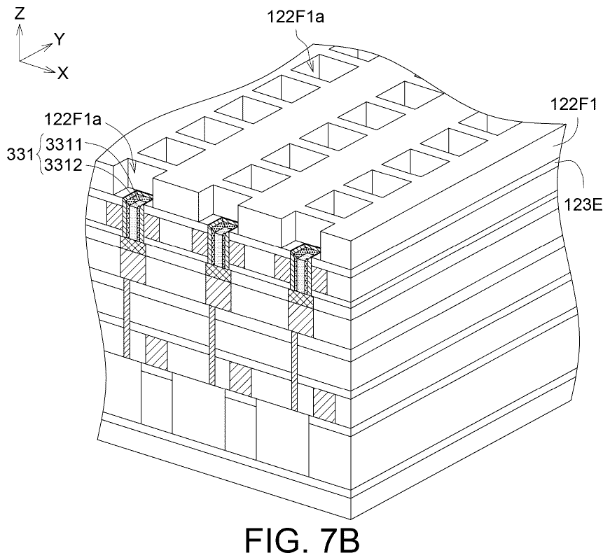

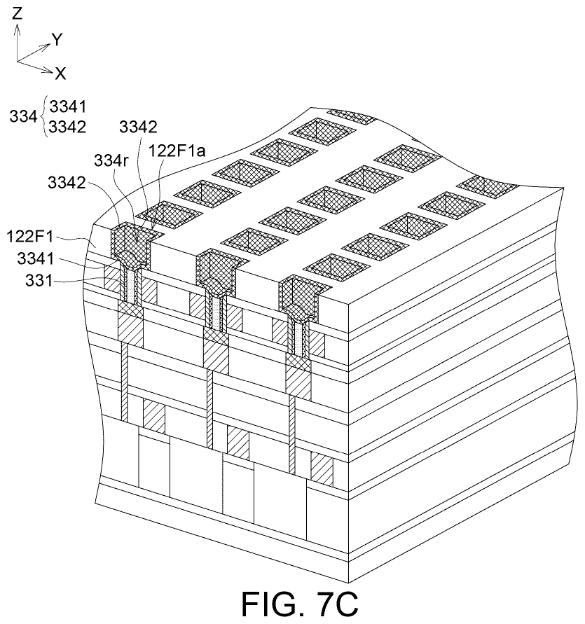

FIGS. 7A to 7C illustrate schematic diagrams of manufacturing processes of the semiconductor device 300 in FIG. 3.

The manufacturing method of the semiconductor device 300 includes the steps the same as or similar to that (FIGS. 5A to 5L and 5P to 5Q) of the semiconductor device 100, and at least one difference is that the forming step of the active channel 331 and the second hydrogen absorption layer 334. The differences are described below with FIGS. 7A to 7C, and other similar or the same steps will not be repeated here.

As illustrated in FIG. 7A, a plurality of the active channels 331 is formed within (or fill) the holes 131a and cover sidewalls of the gate dielectric layers 137. The active channel 331 is contact with the first hydrogen absorption layer 135. The active channel 331 includes the first sub-channel 3311 and the second sub-channel 3312, wherein the first sub-channel 3311 is, for example, a high doping channel, and the second sub-channel 3312 is, for example, a low doping channel. The first sub-channel 3311 is formed over a sidewall of the gate dielectric layer 137. The second sub-channel 3312 is formed over a sidewall of the first sub-channel 3311, and the first sub-channel 3311 may surround the second sub-channel 3312.

As illustrated in FIG. 7B, the first insulation layer 122F1 is formed over the second insulation layer 123E by, for example, deposition. The first insulation layer 122F1 is patterned to form a plurality of the holes 122F1a to expose the active channels 331. The first insulation layer 122F1 may be patterned by using any suitable process, such as by utilizing a patterned photoresist and an etching process, such as a wet or dry etching process.

As illustrated in FIG. 7C, the second hydrogen absorption layers 334 including the bottom portion 3341 and a plurality of the lateral portions 3342 are formed in the holes 122F1a by, for example, deposition, wherein the lateral portions 3342 are connected with the bottom portion 3341. The bottom portion 3341 covers the upper surface of the active channels 331, and the lateral portions 3342 cover sidewalls of the hole 122F1a.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a transistor including a source, a drain, an active channel and at least one hydrogen absorption layer. The source and the drain are disposed on two opposite end surfaces of the active channel. The hydrogen absorption layer may absorb the hydrogen to prevent the hydrogen from entering active channel, and accordingly it may reduce the current leakage and increase the conductivity.

Example embodiment 1: a semiconductor device includes a BEOL structure, a transistor on the BEOL and a transistor formed on the BEOL structure. The transistor includes an active channel, a drain, a source, a second hydrogen absorption layer and a first hydrogen absorption layer. The active channel has a first end surface and a second end surface opposite to the first end surface. The drain is disposed adjacent to the first end surface of the active channel. The source is disposed adjacent to the second end surface of the active channel. The second hydrogen absorption layer is disposed between the drain and the first end surface of the active channel. The first hydrogen absorption layer is disposed between the source and the second end surface of the active channel.

Example embodiment 2 based on Example embodiment 1: the second hydrogen absorption layer is disposed between the drain and the first end surface of the active channel, and the first hydrogen absorption layer is disposed between the source and the second end surface of the active channel.

Example embodiment 3 based on Example embodiment 1: the transistor further includes a gate disposed adjacent to a lateral surface of the active channel.

Example embodiment 4 based on Example embodiment 1: the semiconductor device further includes an insulation layer. The first hydrogen absorption layer is disposed within the insulation layer.

Example embodiment 5 based on Example embodiment 4: the insulation layer and the first hydrogen absorption layer each has an upper surface, and the upper surface of the insulation layer and the second upper surface of the first hydrogen absorption layer are aligned with each other.

Example embodiment 6 based on Example embodiment 1: the semiconductor device further includes an insulation layer having an upper surface. The upper surface of the insulation layer and the first end surface are aligned with each other.

Example embodiment 7 based on Example embodiment 6: the first hydrogen absorption layer has an upper surface, and the upper surface of the first hydrogen absorption layer is contact with the second end surface.

Example embodiment 8 based on Example embodiment 1: the second hydrogen absorption layer has an absorption region within which the drain is disposed.

Example embodiment 9 based on Example embodiment 8: the second hydrogen absorption layer includes a bottom portion and a plurality of lateral portions. The lateral portions are connected with the bottom portion. The bottom portion and the lateral portions form the absorption region.

Example embodiment 10 based on Example embodiment 1: the active channel includes a first sub-channel and a second sub-channel on the first sub-channel. The active channel has a channel region extending to the second sub-channel from the first sub-channel.

Example embodiment 11 based on Example embodiment 10: the second hydrogen absorption layer is disposed within the channel region.

Example embodiment 12: a semiconductor device includes a BEOL structure and a transistor on the BEOL structure. The transistor includes an active channel, a second electrode and a second hydrogen absorption layer. The active channel has a first stepped structure. The second electrode is disposed adjacent to the first stepped structure of the active channel. The second hydrogen absorption layer separates the second electrode from the first stepped structure and includes a second stepped structure matching the first stepped structure.

Example embodiment 13 based on Example embodiment 12: the active channel further has an end surface opposite to the first stepped structure, and the transistor further includes a first electrode disposed adjacent to the end surface of the active channel.

Example embodiment 14 based on Example embodiment 13: the second hydrogen absorption layer is disposed between the second electrode and the first stepped structure of the active channel, and the semiconductor device further includes a first hydrogen absorption layer disposed between the first electrode and the second end surface of the active channel.

Example embodiment 15 based on Example embodiment 14: the semiconductor device further includes an insulation layer. The first hydrogen absorption layer is disposed within the insulation layer.

Example embodiment 16 based on Example embodiment 12: the second hydrogen absorption layer overlaps an entirety of the first end surface of the active channel.

Example embodiment 17: a manufacturing method for a semiconductor device, including the following steps: forming a transistor on a BEOL structure, including: forming a source; forming a first hydrogen absorption layer on the source; forming an active channel on the first hydrogen absorption layer, wherein the active channel has a first end surface and a second end surface, and the first hydrogen absorption layer separates the source from the second end surface; forming a second hydrogen absorption layer on the first end surface of the active channel; and forming a drain on the second hydrogen absorption layer, wherein the second hydrogen absorption layer separates the drain from the first end surface of the active channel.

Example embodiment 18 based on Example embodiment 17: the semiconductor method further includes: forming the source in a first insulation layer; forming a second insulation layer over the first insulation layer, wherein the second insulation layer has a hole exposing the source; and forming the first hydrogen absorption layer on the source through the hole.

Example embodiment 19 based on Example embodiment 18: the manufacturing method further includes: planarizing the insulation layer and the first hydrogen absorption layer.

Example embodiment 20 based on Example embodiment 17: in forming the second hydrogen absorption layer on the first end surface of the active channel, the second hydrogen absorption layer has a lower surface, and the lower surface of the second hydrogen absorption layer overlaps an entirety of the first end surface of the active channel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
a transistor on the substrate, comprising:
an active channel having a first end surface and a second end surface opposite to the first end surface;
a drain disposed adjacent to the first end surface of the active channel;
a source disposed adjacent to the second end surface of the active channel;
a first hydrogen absorption layer separating the source from the second end surface of the active channel; and
a second hydrogen absorption layer separating the drain from the first end surface of the active channel.

2. The semiconductor device according to claim 1, wherein the second hydrogen absorption layer is disposed between the drain and the first end surface of the active channel, and the first hydrogen absorption layer is disposed between the source and the second end surface of the active channel.

3. The semiconductor device according to claim 1, wherein the transistor further comprises:
a gate disposed adjacent to a lateral surface of the active channel.

4. The semiconductor device according to claim 1, further comprising:
an insulation layer;
wherein the first hydrogen absorption layer is disposed within the insulation layer.

5. The semiconductor device according to claim 4, wherein the insulation layer and the first hydrogen absorption layer each has an upper surface, and the upper surface of the insulation layer and the second upper surface of the first hydrogen absorption layer are aligned with each other.

6. The semiconductor device according to claim 1, further comprising:
an insulation layer having an upper surface;
wherein the upper surface of the insulation layer and the first end surface are aligned with each other.

7. The semiconductor device according to claim 6, wherein the first hydrogen absorption layer has an upper surface, and the upper surface of the first hydrogen absorption layer is contact with the second end surface.

8. The semiconductor device according to claim 1, wherein the second hydrogen absorption layer has an absorption region within which the drain is disposed.

9. The semiconductor device according to claim 8, wherein the second hydrogen absorption layer comprises:
a bottom portion; and
a plurality of lateral portions connected with the bottom portion;
wherein the bottom portion and the lateral portions form the absorption region.

10. The semiconductor device according to claim 1, wherein the active channel comprises:
a first sub-channel; and
a second sub-channel on the first sub-channel;
wherein the active channel has a channel region extending to the second sub-channel from the first sub-channel.

11. The semiconductor device according to claim 10, wherein the second hydrogen absorption layer is disposed within the channel recess.

12. A semiconductor device, comprising:
a substrate; and
a transistor on the substrate, comprising:
an active channel having a first stepped structure;
an electrode disposed adjacent to the first stepped structure of the active channel; and
a hydrogen absorption layer separating the electrode from the first stepped structure and comprising a second stepped structure matching the first stepped structure.

13. The semiconductor device as claimed in claim 12, wherein the active channel further has an end surface opposite to the first stepped structure, and the transistor further comprises:
another electrode disposed adjacent to the end surface of the active channel.

14. The semiconductor device as claimed in claim 13, wherein the hydrogen absorption layer is disposed between the electrode and the first stepped structure of the active channel, and the semiconductor device further comprises:
another hydrogen absorption layer disposed between the electrode and the end surface of the active channel.

15. The semiconductor device as claimed in claim 14, further comprising:
an insulation layer;
wherein the another hydrogen absorption layer is disposed within the insulation layer.

16. The semiconductor device as claimed in claim 12, wherein the second hydrogen absorption layer overlaps an entirety of the first end surface of the active channel.

17. A manufacturing method for a semiconductor device, comprising:
forming a transistor on a substrate, comprising:
forming a source;
forming a first hydrogen absorption layer on the source;
forming an active channel on the first hydrogen absorption layer, wherein the active channel has a first end surface and a second end surface, and the first hydrogen absorption layer separates the source from the second end surface;
forming a second hydrogen absorption layer on the first end surface of the active channel; and
forming a drain on the second hydrogen absorption layer, wherein the second hydrogen absorption layer separates the drain from the first end surface of the active channel.

18. The manufacturing method as claimed in claim 17, further comprising:
forming the source in a first insulation layer;
forming a second insulation layer over the first insulation layer, wherein the second insulation layer has a hole exposing the source; and
forming the first hydrogen absorption layer on the source through the hole.

19. The manufacturing method as claimed in claim 18, further comprising:
planarizing the second insulation layer and the first hydrogen absorption layer.

20. The manufacturing method as claimed in claim 17, wherein in forming the second hydrogen absorption layer on the first end surface of the active channel, the second hydrogen absorption layer has a lower surface, and the lower surface of the second hydrogen absorption layer overlaps an entirety of the first end surface of the active channel.
